(19) United States
(12) Patent Application Publication
(10) Pub. No.: US 2013/0338486 A1
(43) Pub. Date: Dec. 19, 2013

(54) DIFFUSION TENSOR MAGNETIC RESONANCE IMAGING METHOD

(71) Applicant: Yu Qing Huang, Shenzhen (CN)

(72) Inventor: Yu Qing Huang, Shenzhen (CN)

(21) Appl. No.: 13/917,895

(22) Filed: Jun. 14, 2013

(30) Foreign Application Priority Data
Jun. 14, 2012 (CN) 201210196558.2

(51) Int. Cl. G01R 33/563

(52) U.S. Cl. CPC G01R 33/56341
USPC 600/413

(57) ABSTRACT

In a diffusion tensor magnetic resonance imaging method for imaging a myocardial fiber structure, the diaphragm position of a subject is detected and a determination is made as to whether the diaphragm position of the subject falls into the acceptance region or not. If it does not, continue the diaphragm position of the examination subject is continued to be detected. If and when the diaphragm position is in the acceptance region, an echo planar imaging sequence with stimulated echo is executed with two electrocardiogram triggers, so as to acquire diffusion tensor image data of the myocardial fiber structure. The cardiac DTI image data thus can be obtained under free respiration of the subject, and the influence of respiratory movement is reduced and the scanning time is shortened.

### BACKGROUND OF THE INVENTION

1. Field of the Invention

The present invention relates to the technical field of magnetic resonance imaging, in particular to a diffusion tensor magnetic resonance imaging method, especially a diffusion tensor magnetic resonance imaging method for imaging a myocardial fiber structure.

2. Description of the Prior Art

Cardiac Diffusion Tensor Imaging (DTI) provides an effective and noninvasive detection means for the reconstruction of an image of a myocardial fiber structure, and is capable of being used for measuring the abnormal deformation of myocardial structure in some specific heart diseases.

In existing technology, the echo planar imaging (EPI) technology of stimulated echo acquisition mode (STEAM) having two ECG triggers (electrocardiogram triggers) is a common mode for acquiring the cardiac DTI. This technology uses two electrocardiogram triggers that are added in the STEAM EPI sequence, with identical diffusion encoding gradient pulses being activated at the same phase-delay (φ) between two consecutive heartbeat periods (i.e., the time period between two consecutive ECGs). Specifically, the STEAM EPI sequence is divided into two parts according to time sequences: the first part includes a first 90 degree radio-frequency (RF) pulse, a first diffusion encoding gradient pulse (DG), a second 90 degree radio-frequency (RF) pulse and a STEAM mixing time; and the second part includes a third 90 degree radio-frequency (RF) pulse and a second diffusion encoding gradient pulse (DG). The two electrocardiogram triggers are set before the first part of the STEAM EPI sequence and before the second part of the STEAM EPI sequence, respectively. It is thus apparent that a single execution of STEAM EPI sequence scanning with two electrocardiogram triggers involves two heartbeat periods, and a corresponding diffusion encoding gradient is activated after a delay of the same time for each electrocardiogram trigger. In this way, the phase-delay (φ) between the first electrocardiogram trigger and the first diffusion gradient pulse can be ensured to be equal to the phase-delay (φ) between the second electrocardiogram trigger and the second diffusion gradient pulse, thereby effectively avoiding signal attenuation caused by myocardial movement. Of course, based on the different requirements of users, the delay time between the electrocardiogram trigger and the diffusion encoding gradient can be artificially adjusted to acquire signals of different heartbeat periods, such as the signals of systole and diastole of the heart.

The diffusion sensitivity b can be calculated according to formula (1) using the abovementioned STEAM EPI technology having two electrocardiogram triggers based on the Bloch-Terrey function.

b=K²(Δ−δ/3) (1)

wherein, K=2πλδG is a space modulation vector, in which G and δ are the amplitude of the diffusion encoding gradient pulse and the time, respectively, and λ is the proton gyromagnetic ratio. Δ is the interval between the two diffusion encoding gradient pulses.

After acquiring the data of diffusion sensitivity b, the logarithm of I/I₀ is taken by linear inversion and the diffusion tensor image data in each time frame is calculated aiming at the diffusion weighted image data.

log(I/I₀)=−(Δ−δ/3)K^{T}\vec{D}K (2)

wherein, I is the diffusion weighted image data, i.e., the image data with the added diffusion encoding gradient; I₀ is the non-diffusion weighted image data, i.e., the image data without adding the diffusion encoding gradient; and \vec{D} is the diffusion tensor to be measured. After scanning using the diffusion tensor encoding gradients in six different directions or more, the measured cardiac diffusion tensor \vec{D} can be obtained through corresponding data post processing and finally the myocardial fiber structure is reconstructed.

However, the problem with the above-mentioned STEAM EPI technology having two electrocardiogram triggers is that the influence of respiratory movement by the patient cannot be effectively eliminated, therefore patients are required to cooperate by strictly holding their breath during signal acquisition, i.e., to hold their breath intermittently several times, even though breathholding is a significant challenge for certain patients. In addition, since intermittently holding the breath several times often results in the prolonging of the scanning time, generally speaking, approximately 30 minutes are needed to acquire the cardiac DTI data using the existing technology.

### SUMMARY OF THE INVENTION

The present invention provides a diffusion tensor magnetic resonance imaging method for imaging a myocardial fiber structure, that includes detecting the diaphragm position of a subject, determining whether the diaphragm position of the subject falls into the acceptance region or not. If it does not, the diaphragm position of the examination subject continues to be detected, and only if and when it falls within the acceptance region, the method proceeds an echo planar imaging sequence of stimulated echo having two EGG triggers, so as to acquire the diffusion tensor image data of myocardial fiber structure.

Preferably, the average value obtained by detecting the diaphragm position of a subject during a set time period is taken as the mid-value of the acceptance region, and the range of the acceptance region can be obtained by using the mid-value of the acceptance region to add or subtract the setup parameter.

Preferably, the diaphragm position of the subject is detected by a two-dimensional gradient echo sequence with low resolution.

Preferably, the set time period is 50-60 s.

Preferably, the setup parameter is 2.5 millimeters.

Preferably, a fat-suppression module is used before the first and the third radio-frequency pulses of the echo planar imaging sequence of stimulated echo having two electrocardiogram triggers.

In the embodiments of the present invention the cardiac DTI image data can be obtained when the subject respirates freely by combining the technology of the echo planar imaging (EPI) of STEAM having two electrocardiogram (ECG) triggers with the technology of the two-dimensional (2D) Prospective Acquisition Correction (PACE). Experimental data indicates that the influence of respiratory movement is greatly reduced and the scanning time is substantially shortened, so as to solve the aforementioned problems in the existing technology.

At the same time, the technical solution of the present invention does not bring further complexity and limitation into the sequence, and the DTI image data can be accomplished through the existing image reconstruction algorithm. Moreover, the desired 3D myocardial fiber image can be finally reconstructed from the initial data. The entire scanning process can be completed within 5 minutes. The experimental results show that the basic ventricular fiber helical structure can be acquired from the final 3D myocardial fiber image.

### BRIEF DESCRIPTION OF THE DRAWINGS

FIG. 1 is a schematic diagram of the STEAM echo planar imaging sequence having two EGG triggers combining 2D PACE according to the embodiments of the present invention.

FIG. 2 is a block diagram of the STEAM echo planar imaging method combining 2D PACE according to embodiments of the present invention.

FIG. 3A is a two-dimensional DWI image of the third layer and a two-dimensional DWI image of the fourth layer in the direction of the cardiac short-axis of the subject obtained using the present invention.

FIG. 3B is the two-dimensional fractional anisotropy images of different positions of five layers in the direction of the cardiac short-axis of the subject obtained using the present invention.

FIG. 3C is an average diffusion trajectory image of the water molecules in the first layer of myocardium in the direction of the cardiac short-axis of the subject obtained using the present invention.

FIG. 3D is a three-dimensional myocardial fiber structure image of the left ventricle of the subject obtained using the present invention.

### DESCRIPTION OF THE PREFERRED EMBODIMENTS

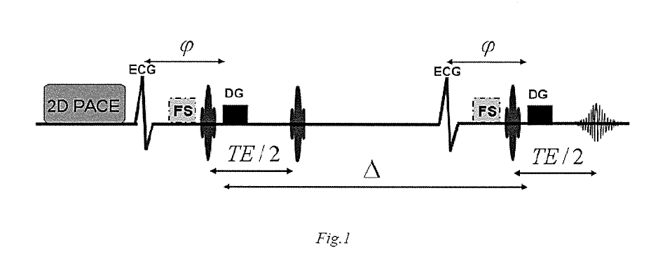

As mentioned above, respiratory movement has great influence on acquiring the cardiac DTI and the subject is usually forced to hold his/her breath intermittently several times in existing cardiac DTI to attenuate the influence of the respiratory movement. In order to solve this problem, FIG. 1 shows a schematic diagram of the STEAM echo planar imaging sequence of cardiac DTI according to the particular embodiment of the present invention. In this particular embodiment, as shown in FIG. 1, two-dimensional (2D) Prospective Acquisition Correction (PACE) technology is employed to correct the respiratory movement during the acquisition of the cardiac DTI data, so that the subject can respire freely during the measurement.

In the applied two-dimensional PACE technology, the diaphragm position of a subject is detected using two-dimensional gradient echo sequence with low resolution. First, a brief “learning time” is used to analyze the respiratory state of the subject and the mid-value of the “acceptance region” of the diaphragm position is automatically calculated, and the range of the “acceptance region” is determined by setting artificially or automatically by the system; and then, the gated data acquisition process begins: the DTI data acquisition is allowed only when the diaphragm position falls into the “acceptance region”. In other words, the diaphragm position in the “acceptance region” indicates that the amplitude of the respiratory movement of the subject is relatively stable, usually being the end exhalation period. Therefore, the influence of the respiratory movement can be greatly reduced when the DTI data are obtained as the diaphragm position falls into the “acceptance region”.

Experimentally, a number of diaphragm positions were acquired using a “learning time” of 50-60 s by means of the two-dimensional gradient echo sequence with low resolution, and gave the mid-value of the “acceptance region” of the diaphragm position by calculating the average value of the acquired individual diaphragm positions. The range of the “acceptance region” of the diaphragm position can either be artificially set or automatically set by the system. Those skilled in the art can determine the “learning time” and the range of the “acceptance region” according to needs.

Furthermore, in order to suppress the fat signal, the FatSat (FS) fat-suppression module was used before the first radio-frequency and the third radio-frequency pulses. Since the residual fat signal may recover during the relatively long STEAM mixing time, it was very necessary to use the FatSat (fs) fat-suppression module before the third radio-frequency pulse.

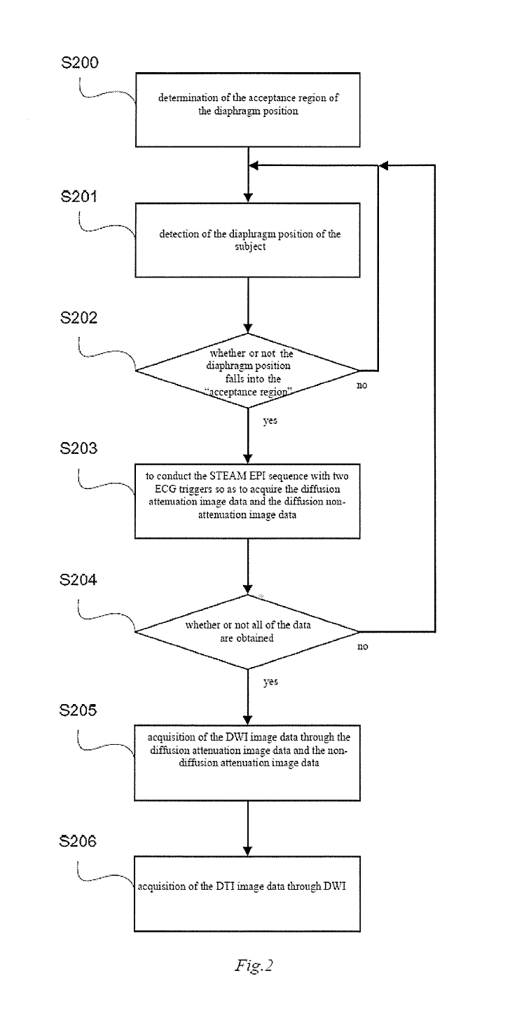

Particular embodiments of the present invention are described below in detail by individual steps by referring to FIG. 2. In this case, in order to obtain the reconstruction image of the myocardial fiber structure, it is required to acquire the initial data and to calculate the diffusion tensor of the initial data so as to get the Diffusion Tensor Images (DTI). The initial data are the Diffusion Weighted Images (DWI) in various different directions. The following sequences and reconstruction steps of the particular embodiments of the present invention are carried out to acquire the diffusion weighted images.

Step S200, determination of the “acceptance region” of the diaphragm position.

The detection of the diaphragm position using the two-dimensional gradient echo sequence with low resolution: a brief “learning time” is used to analyze the respiratory state of the subject and the mid-value of the “acceptance region” of the diaphragm position is automatically calculated, and the range of the “acceptance region” is determined by setting artificially or automatically by the system.

In the particular embodiment, the inventors acquired a plurality of diaphragm positions using a “learning time” of 50-60 s by means of a two-dimensional gradient echo sequence with low resolution, and acquired the mid-value of the “acceptance region” of the diaphragm positions through calculating the average value of the acquired individual diaphragm positions; and the range of the “acceptance region” of the diaphragm positions could be either artificially set or automatically set by the system, preferably the mid-value ±2.5 mm of the “acceptance region” is served as the range of the “acceptance region” of the diaphragm positions. Those skilled in the art can determine the “learning time” and the range of the “acceptance region” according to needs.

Step S201, detection of the diaphragm position of the subject.

In the applied two-dimensional PACE technology, the two-dimensional gradient echo sequence with low resolution is continuously used to detect the diaphragm position after determining the “acceptance region” of the diaphragm position.

Step S202, judgment whether the diaphragm position of the subject falls into the “acceptance region” or not. If it falls into the “acceptance region”, then proceed to step S203; if it does not fall into the “acceptance region”, then repeat step S201.

The DTI data can be acquired only when the diaphragm position falls into the “acceptance region”. In other words, the diaphragm position in the “acceptance region” indicates that the respiratory movement of the subject is relatively stable, therefore, the influence of the respiratory movement can be greatly reduced when the DTI data are obtained as the diaphragm position falls into the “acceptance region”. When the diaphragm position does not fall into the “acceptance region”, the detection is continued and the next step begins until the diaphragm position of the subject falls into the “acceptance region”.

Step S203, proceeding to echo planar imaging (EPI) sequence of stimulated echo (STEAM) having two electrocardiogram (ECG) triggers.

First, as described in the background art, proceeding to the first electrocardiogram (ECG) trigger, then proceeding to the first part of the STEAM EPI sequence; and then, proceeding to the second electrocardiogram (ECG) trigger, then proceeding to the second part of the STEAM EPI sequence. In this case, the first part of the STEAM EPI comprises a first 90 degree radio-frequency (RF) pulse, a first diffusion encoding gradient (DG) pulse, a second 90 degree radio-frequency (RF) pulse and a STEAM mixing time; and the second part of the STEAM EPI sequence comprises a third 90 degree radio-frequency (RF) pulse and a second diffusion encoding gradient (DG) pulse.

A single execution of the STEAM EPI sequence with two ECG involves two heartbeat periods, and the corresponding diffusion encoding gradient is exerted after a delay of the same time for each electrocardiogram trigger. In this way, the phase-delay (φ) between the first electrocardiogram trigger (ECG) and the first diffusion gradient pulse can be ensured to be equal to the phase-delay (φ) between the second electrocardiogram trigger (ECG) and the second diffusion gradient pulse, thereby effectively avoiding the signal attenuation caused by myocardial pulsation. Of course, based on the different requirements of users, the delay time between the electrocardiogram trigger and the diffusion encoding gradient can be artificially adjusted to acquire signals of different heartbeat periods, such as the signals of systole and diastole of the heart.

In this particular embodiment, the diffusion weighted image data I (i.e., the image data with the added diffusion encoding gradient) was acquired in 6 different directions at 5 layers of different positions in the direction of the cardiac short-axis of the subject and corresponding non-diffusion weighted image data I₀ of each layer (i.e., the image data without adding the diffusion encoding gradient).

Furthermore, in order to suppress the fat signal, the FatSat (FS) fat-suppression module is used before the first radio-frequency and the third radio-frequency pulses. Since the residual fat signal may recover during the relatively long STEAM mixing time, it was very necessary to use the FatSat (fs) fat-suppression module before the third radio-frequency pulse.

Therefore, the diffusion coefficient D is calculated by means of formula (3) after obtaining the diffusion weighted image data I and the non-diffusion weighted image data I₀ in various directions:

$$I ∝ \frac{1}{2} {I}_{0} {e}^{- ( \frac{RR duration}{{T}_{1}} + \frac{TE}{{T}_{2}} )} {e}^{- {γ}^{2} {G}^{2} {δ}^{2} ( Δ - \frac{δ}{3} ) D} \qquad ( 3 )$$

in which RR duration is the heartbeat period (i.e., the time interval between two consecutive ECGs), T₁ is longitudinal relaxation time, T₂ is transverse relaxation time, TE is echo time, λ is proton gyromagnetic ratio, G is the amplitude of the diffusion encoding gradient pulse, δ is the time of the diffusion encoding gradient pulse, and Δ is the interval between two diffusion encoding gradient pulses.

S204, judgment whether or not all of the data are obtained.

Determining whether or not all of the data are obtained, proceeding to continue the two-dimensional prospective acquisition correction (PACE) on the subject if not all of the data has been obtained and then collecting the corresponding data, and proceeding to the next step if all of the data have been obtained.

In the particular embodiment, the inventors collected the diffusion weighted image data I (i.e., the image data with the added diffusion encoding gradient) in 6 different directions at 5 layers of different positions in the direction of the cardiac short-axis of the subject and corresponding non-diffusion weighted image data I₀ of each layer (i.e., the image data without adding the diffusion encoding gradient). Whether or not all of the diffusion weighted image data I in 6 different directions at 5 layers of different positions and corresponding non-diffusion weighted image data I₀ of each layer have been collected are judged in this step.

Step S205, Fourier transform (FFT) was carried out on the diffusion weighted image data I and the non-diffusion weighted image data I₀ so as to acquire the DWI image data of various different directions.

Step S206, calculation of the diffusion tensor with respect to the DWI image data of various different directions was carried out so as to acquire the DTI image data.

Details of calculation method are described in the description of the prior art.

In order to validate the feasibility of the present invention, the heart of a healthy subject was scanned by the inventors using this novel method, and two-dimensional fractional anisotropy images and a three-dimensional myocardial fiber structure image can be obtained after certain data post processing. The experimental scannings were carried out in a 1.5T Siemens whole body imager; a 12-unit matrix body coil was employed; the volunteer was in a free respiration state during the whole scanning process; and the scanning time was only 5 minutes due to that the subject was not required to hold his/her breath, whereas more than 30 minutes would be needed in an original method under the same parameters.

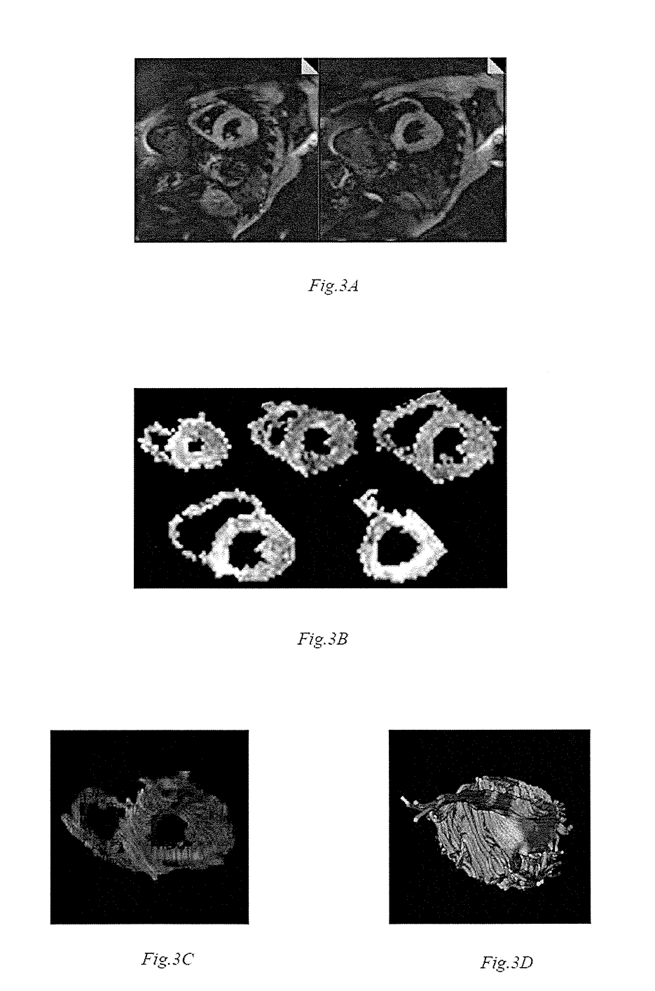

FIG. 3A, FIG. 3B, FIG. 3C and FIG. 3D show the scanning results during the systole period of the heart of the subject. FIG. 3A is a diffusion schematic diagram of the third layer data and the fourth layer data in the direction of the cardiac short-axis according to the particular embodiment of the present invention. FIG. 3B is the two-dimensional fractional anisotropy images of the different positions of the data of the 5 layers in the direction of the cardiac short-axis according to the particular embodiment of the present invention. FIG. 3C is an average diffusion trajectory image of the water molecules in the myocardium in the direction of the cardiac short-axis obtained on the basis of the data reconstruction of the first layer according to the particular embodiment of the present invention. FIG. 3D is a three-dimensional myocardial fiber structure image of the left ventricle obtained on the basis of data reconstruction of the 5 layers according to the particular embodiment of the present invention. It can be seen from the average diffusion trajectory image of the water molecules of the first layer in the direction of the cardiac short-axis that the diffusion direction of the water molecules in the endocardium is different from the diffusion direction of the water molecules in the epicardium of the left ventricle, reflecting the difference of the fiber orientations in the endocardium and the epicardium. However, the three-dimensional structure image of the myocardial fibers of the left ventricle which is obtained by reconstruction can reflect the basic structure characteristics of the myocardial fibers in the left ventricle, with the epicardium fibers being presented in a left-handed helix ascending structure as seen from the top of the heart to the apex of the heart. Since the volunteer is not needed to hold his/her breath during the whole scanning process and the scanning time is in a reasonable range for clinical applications, this method provides an effective means for detecting the myocardial structure of the human body, and it has potential application value for understanding the relationship between the myocardial structural deformation and the pathological mechanisms of the heart.

The present invention discloses a diffusion tensor magnetic resonance imaging method of the myocardial fiber structure, which comprises: detecting the diaphragm position of a subject; determining whether the diaphragm position of the subject falls into the acceptance region or not, if it does, proceed to the following steps, and if it does not, continue detecting the diaphragm position of the examination subject and following steps; and proceeding to echo planar imaging sequence of stimulated echo having two electrocardiogram triggers, so as to acquire the diffusion tensor image data of the myocardial fiber structure. By means of the present invention, the cardiac DTI image data can be obtained when the subject respires freely; the influence by respiratory movement is greatly reduced and the time needed for scanning is substantially shortened; and meanwhile, the present invention does not bring further complexity and limitation into the magnetic resonance system.

Although modifications and changes may be suggested by those skilled in the art, it is the intention of the inventor to embody within the patent warranted hereon all changes and modifications as reasonably and properly come within the scope of the inventor's contribution to the art.

I claim as my invention:

1. A diffusion tensor magnetic resonance imaging method for imaging a myocardial fiber structure, comprising:
detecting a diaphragm position of a respirating subject and generating diaphragm position information representing the detected diaphragm position;
supplying said diaphragm position information to a computerized processor and, in said computerized processor, automatically determining, from the diaphragm position information, whether the diaphragm position of the subject is within an acceptance region and, if not, repeatedly detecting the diaphragm position and determining whether the diaphragm position of the subject is in said acceptance region; and
when said diaphragm position of the subject is determined to be within said acceptance region, automatically proceeding to operate a magnetic resonance data acquisition unit by implementing an echo planar imaging sequence, with two electrocardiogram triggers, to acquire diffusion tensor image data of a myocardial fiber structure of the subject during stimulated echoes of said echo planar imaging sequence.

2. A diffusion tensor magnetic resonance imaging method as claimed in claim 1 comprising, in said processor, determining, from said diaphragm position information, an average value of said diaphragm position of the subject during a predetermined time period and using said average value as a mid-value of said acceptance region, and setting a range of said acceptance region by adding and subtracting, respectively, a predetermined value from said mid-value.

3. A diffusion tensor magnetic resonance imaging method as claimed in claim 2 comprising setting said time period to be in a range between 50 and 60 seconds.

4. A diffusion tensor magnetic resonance imaging method as claimed in claim 2 comprising adding and subtracting a value of 2.5 millimeters to and from said mid-value to obtain said range of said acceptance region.

5. A diffusion tensor magnetic resonance imaging method as claimed in claim 2 comprising setting said time period to be in a range between 50 and 60 seconds, and adding and subtracting a value of 2.5 millimeters to and from said mid-value to obtain said range of said acceptance region.

6. A diffusion tensor magnetic resonance imaging method as claimed in claim 1 comprising detecting said diaphragm position, and generating said diaphragm position information, by operating said magnetic resonance data acquisition unit to execute a two-dimensional radio echo sequence with low resolution.

7. A diffusion tensor magnetic resonance imaging method as claimed in claim 1 wherein said echo planar imaging sequence comprises radiation of first, second and third radio-frequency pulses, and comprising operating said magnetic resonance data acquisition unit to execute a fat-suppression module before radiation of each of said first and third radio-frequency pulses of said echo planar imaging sequence.
